(19) United States
(12) Patent Application Publication
(10) Pub. No.: US 2022/0319800 A1
(43) Pub. Date: Oct. 6, 2022

(54) PLASMA PROCESSING SYSTEM, TRANSFER ARM, AND METHOD OF TRANSFERRING ANNULAR MEMBER

(71) Applicant: Tokyo Electron Limited, Tokyo (JP)

(72) Inventor: Nobuyuki NAGAYAMA, Miyagi (JP)

(73) Assignee: Tokyo Electron Limited, Tokyo (JP)

(21) Appl. No.: 17/706,590

(22) Filed: Mar. 29, 2022

(30) Foreign Application Priority Data
Mar. 30, 2021 (JP) 2021-057155

(51) Int. Cl. H01J 37/20; H01J 37/32

(52) U.S. Cl. CPC H01J 37/20; H01J 37/3244; H01J 2237/202; H01J 2237/2007

(57) ABSTRACT

There is a plasma processing system comprising: a processing chamber; a substrate support disposed in the processing chamber; an annular member disposed at an outer edge of the substrate support and having a bottom surface in contact with the substrate support, an upper surface on the opposite side of the bottom surface, and a side surface that connects the upper surface and the bottom surface; and a transfer arm configured to load/unload the annular member into/from the processing chamber while holding the upper surface or the side surface.

### CROSS-REFERENCE TO RELATED APPLICATION

This application claims priority to Japanese Patent Application No. 2021-057155 filed on Mar. 30, 2021, the entire contents of which are incorporated herein by reference.

### TECHNICAL FIELD

The present disclosure relates to a plasma processing system, a transfer arm, and a method of transferring an annular member.

### BACKGROUND

In a plasma processing apparatus, an annular member disposed around a processing substrate is used (see, Japanese Patent Application Publication No. 2012-216614 and No. 2011-054933). The annular member deteriorates as it is used, and thus needs to be replaced.

### SUMMARY

The present disclosure provides a technique for transferring an annular member disposed around a processing substrate.

In accordance with an aspect of the present disclosure, there is a plasma processing system comprising: a processing chamber; a substrate support disposed in the processing chamber; an annular member disposed at an outer edge of the substrate support and having a bottom surface in contact with the substrate support, an upper surface on the opposite side of the bottom surface, and a side surface that connects the upper surface and the bottom surface; and a transfer arm configured to load/unload the annular member into/from the processing chamber while holding the upper surface or the side surface.

### BRIEF DESCRIPTION OF THE DRAWINGS

The objects and features of the present disclosure will become apparent from the following description of embodiments, given in conjunction with the accompanying drawings, in which:

FIG. 1 explains a configuration example of an example of a plasma processing system according to an embodiment;

FIG. 2 is a cross-sectional view showing a schematic configuration of an example of a substrate processing system according to an embodiment;

FIGS. 3 to 5 explain a method of transferring an annular member that is an example of an annular member in a plasma processing system according to the embodiment;

FIG. 6 explains a holding method (1) in the method of transferring an annular member that is an example of the annular member in the plasma processing system according to the embodiment;

FIG. 7 explains a holding method (2) in the method of transferring an annular member that is an example of the annular member in the plasma processing system according to the embodiment;

FIGS. 8 and 9 explain a holding method (3) in the method of transferring an annular member that is an example of the annular member in the plasma processing system according to the embodiment;

FIGS. 10 and 11 explain a holding method (4) in the method of transferring an annular member that is an example of the annular member in the plasma processing system according to the embodiment;

FIG. 12 explains a holding method (5) in the method of transferring an annular member that is an example of the annular member in the plasma processing system according to the embodiment;

FIG. 13 explains a holding method (6) in the method of transferring an annular member that is an example of the annular member in the plasma processing system according to the embodiment;

FIG. 14 explains a holding method (7) in the method of transferring an annular member that is an example of the annular member in the plasma processing system according to the embodiment; and

FIG. 15 explains a transfer arm that is an example of the annular member in the plasma processing system according to the embodiment.

### DETAILED DESCRIPTION

Hereinafter, embodiments for implementing the present disclosure will be described with reference to the accompanying drawings. Throughout this specification and the drawings, like reference numerals will be given to substantially like parts, and redundant description thereof will be omitted. For ease of understanding, the scale of individual components in the drawings may be different from the actual scale.

Directions such as parallel, right-angled, orthogonal, horizontal, vertical, up and down, and left and right are allowed to deviate without spoiling the effect of the embodiment. The shape of a corner is not limited to a right angle and may be rounded in an arch shape. The terms parallel, right-angled, orthogonal, horizontal, and vertical may include substantially parallel, substantially right-angled, substantially orthogonal, substantially horizontal, and substantially vertical, respectively.

<Plasma Processing System>

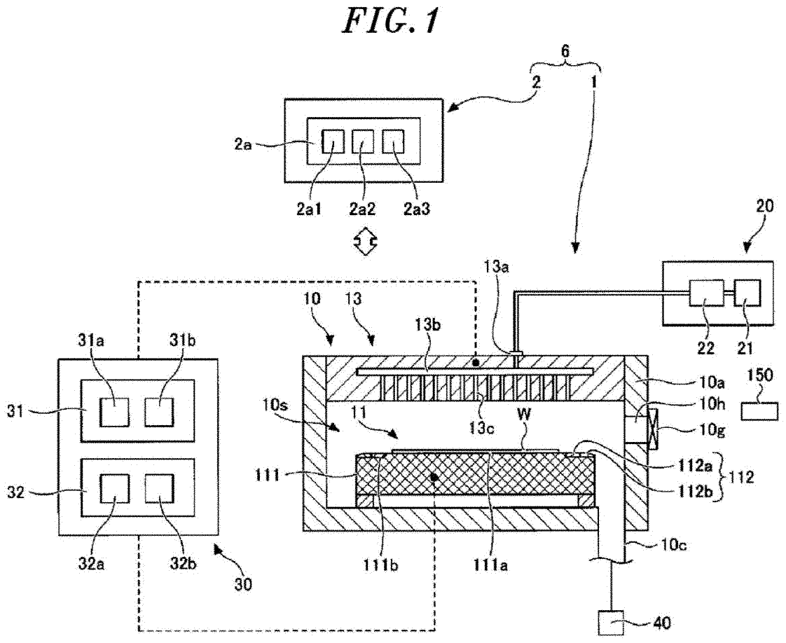

Hereinafter, a configuration example of a plasma processing system 6 will be described with reference to FIG. 1.

The plasma processing system 6 includes a capacitively coupled plasma processing apparatus 1 and a controller 2. The capacitively coupled plasma processing apparatus 1 includes a plasma processing chamber 10, a gas supplier 20, a power supply 30, and an exhaust system 40. The plasma processing apparatus 1 further includes a substrate support 11 and a gas inlet portion. The gas inlet portion is configured to introduce at least one processing gas into the plasma processing chamber 10. The gas inlet portion includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas to the plasma processing space 10a, and at least one gas discharge port for discharging a gas from the plasma processing space. The sidewall 10a is grounded. The shower head 13 and the substrate support 11 are electrically isolated from the plasma processing chamber 10.

The substrate support 11 includes a main body 111 and a ring assembly 112. The main body 111 has a central region (substrate supporting surface) 111a for supporting a substrate (wafer) W and an annular region (ring supporting surface) 111b for supporting the ring assembly 112. The annular region 111b of the main body 111 surrounds the central region 111a of the main body 111 in plan view. The substrate W is disposed on the central region 111a of the main body 111, and the ring assembly 112 is disposed on the annular region 111b (outer edge) of the main body 111 to surround the substrate W on the central region 111a of the main body 111. In one embodiment, the main body 111 includes a base and an electrostatic chuck. The base includes a conductive member. The conductive member of the base functions as a lower electrode. The electrostatic chuck is placed on the base. An upper surface of the electrostatic chuck has the substrate supporting surface 111a. The ring assembly 112 includes one or more annular members, and at least one of them is an edge ring. The ring assembly 112 of the present embodiment shown in FIG. 1 includes an edge ring 112a and a cover ring 112b. Although it is not illustrated, the substrate support 11 may include a temperature control module configured to control a temperature of at least one of the electrostatic chuck, the ring assembly 112, or the substrate to a target temperature. The temperature control module may include a heater, a heat transfer medium, a flow path, or a combination thereof. A heat transfer fluid such as brine or a gas flows through the flow path. Further, the substrate support 11 may include a heat transfer gas supplier configured to supply a heat transfer gas to a space between the backside of the substrate W and the substrate supporting surface 111a.

The shower head 13 is configured to introduce at least one processing gas from the gas supplier 20 into the plasma processing space 10s. The shower head 13 has at least one gas supply port 13a, at least one gas diffusion space 13b, and a plurality of gas inlet ports 13c. The processing gas supplied to the gas supply port 13a passes through the gas diffusion space 13b and is introduced into the plasma processing space 10s from the gas inlet ports 13c. Further, the shower head 13 includes a conductive member. The conductive member of the shower head 13 functions as an upper electrode. The gas inlet portion may include, in addition to the shower head 13, one or multiple side gas injector (SGI) attached to one or multiple openings formed in the sidewall 10a.

The gas supplier 20 may include at least one gas source 21 and at least one flow controller 22. In one embodiment, the gas supplier 20 is configured to supply at least one processing gas from the corresponding gas source 21 to the shower head 13 through the corresponding flow rate controller 22. The flow rate controllers 22 may include, e.g., a mass flow controller or a pressure-controlled flow rate controller. Further, the gas supplier 20 may include one or more flow rate modulation devices for modulating the flow rate of at least one processing gas or causing it to pulsate.

The power supply 30 includes an RF power supply 31 connected to the plasma processing chamber 10 through at least one impedance matching circuit. The RF power supply 31 is configured to supply at least one RF signal (RF power), such as a source RF signal and a bias RF signal, to the conductive member of the substrate support 11 and/or the conductive member of the shower head 14. Accordingly, plasma is produced from at least one processing gas supplied to the plasma processing space 10s. Therefore, the RF power supply 31 may function as at least a part of a plasma generator configured to generate plasma from one or more processing gases in the plasma processing chamber 10. Further, by supplying the bias RF signal to the conductive member of the substrate support 11, a bias potential is generated at the substrate W, and ions in the produced plasma can be attracted to the substrate W.

In one embodiment, the RF power supply 31 includes a first RF generator 31a and a second RF generator 31b. The first RF generator 31a is connected to the conductive member of the substrate support 11 and/or the conductive member of the shower head 13 through at least one impedance matching circuit, and is configured to generate a source RF signal (source RF power) for plasma generation. In one embodiment, the source RF signal has a frequency within a range of 13 MHz to 150 MHz. In one embodiment, the first RF generator 31a may be configured to generate a plurality of source RF signals having different frequencies. The generated one or multiple source RF signals are supplied to the conductive member of the substrate support 11 and/or the conductive member of the shower head 13. The second RF generator 31b is connected to the conductive member of the substrate support 11 through at least one impedance matching circuit, and is configured to generate a bias RF signal (bias RF power). In one embodiment, the bias RF signal has a frequency lower than that of the source RF signal. In one embodiment, the bias RF signal has a frequency within a range of 400 kHz to 13.56 MHz. In one embodiment, the second RF generator 31b may be configured to generate a plurality of bias RF signals having different frequencies. The generated one or multiple bias RF signals are supplied to the conductive member of the substrate support 11. Further, in various embodiments, at least one of the source RF signal and the bias RF signal may pulsate.

The power supply 30 may include a DC power supply 32 connected to the plasma processing chamber 10. The DC power supply 32 includes a first DC generator 32a and a second DC generator 32b. In one embodiment, the first DC generator 32a is connected to the conductive member of the substrate support 11 and is configured to generate a first DC signal. The generated first bias DC signal is applied to the conductive member of the substrate support 11. In one embodiment, the first DC signal may be applied to another electrode, such as an electrode in an electrostatic chuck. In one embodiment, the second DC generator 32b is connected to the conductive member of the shower head 13 and is configured to generate a second DC signal. The generated second DC signal is applied to the conductive member of the shower head 13. In various embodiments, at least one of the first and second DC signals may pulsate. The first DC generator 32a and the second DC generator 32b may be provided in addition to the RF power supply 31, and the first DC generator 32a may be provided instead of the second RF generator 31b.

The exhaust system 40 may be connected to a gas outlet 10e disposed at a bottom portion of the plasma processing chamber 10, for example. The exhaust system 40 may include a pressure control valve and a vacuum pump. The pressure control valve adjusts a pressure in the plasma processing space 10s. The vacuum pump may include a turbo molecular pump, a dry pump, or a combination thereof.

The plasma processing system 6 including a loading/unloading port 10h on the sidewall 10a of the plasma processing chamber 10. The plasma processing system 6 further includes a gate valve 10g for opening and closing the loading/unloading port 10h. The plasma processing system 6 further includes a transfer arm 150 for loading/unloading the substrate W or the annular member of the ring assembly 112. The transfer arm 150 passes through the loading/unloading port 10h to transfer the substrate W or the annular member of the ring assembly 112.

The controller 2 processes computer-executable instructions that cause the plasma processing apparatus 1 to perform various steps described in the present disclosure. The controller 2 may be configured to control individual components of the plasma processing apparatus 1 to perform various steps described herein. In one embodiment, a part or all of the controller 2 may be included in the plasma processing apparatus 1. The controller 2 may include, e.g., a computer 2a. The computer 2a may include, e.g., a central processing unit (CPU) 2al, a storage device 2a2, and a communication interface 2a3. The central processing unit 2al may be configured to perform various control operations based on a program stored in the storage device 2a2. The storage device 2a2 may include a random access memory (RAM), a read only memory (ROM), a hard disk drive (HDD), a solid state drive (SSD), or a combination thereof. The communication interface 2a3 may communicate with the plasma processing apparatus 1 through a communication line such as a local area network (LAN) or the like.

(Configuration of Substrate Processing System 5)

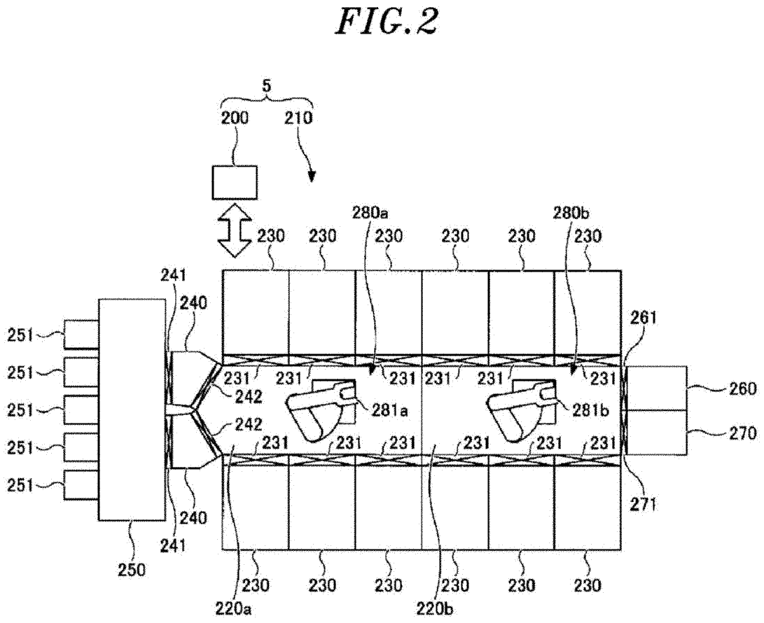

FIG. 2 is a cross-sectional view showing a schematic configuration of an example of a substrate processing system according to an embodiment. The substrate processing system 5 shown in FIG. 2 is configured to process wafers individually and perform various treatments such as plasma processing and the like on each wafer (e.g., a semiconductor wafer).

The substrate processing system 1 includes a processing system body 210 and a controller 200 for controlling the processing system body 10. As shown in FIG. 1, for example, the processing system body 210 includes vacuum transfer modules 220a and 220b, a plurality of process modules 230, a plurality of load-lock modules 240, an equipment front end module (EFEM) 250, an ashing module 260, and a storage module 270. In the following description, each of the vacuum transfer modules 220a and 220b may also be referred to as “VTM,” each of the process modules 230 may also be referred to as “PM,” and each of the load-lock modules 240 may also be referred to as “LLM.”

Each of the VTMs 220a and 220b has a substantially quadrangular shape in plan view. The PMs 230 are connected to two opposite side surfaces of each of the VTMs 220a and 220b. Further, the LLMs 240 are connected to one of the other two opposite side surfaces of the VTM 220a, and a path (not shown) to connect with the VTM 220b is connected to the other of the two opposite side surfaces. The angle between the side surfaces of the VTM 220a to which the LLMs 240 are connected is determined depending on the shapes of the two LLMs 240. The VTM 220b is connected to the VTM 220a through the path (not shown). The VTMs 220a and 220b have vacuum chambers where robot arms 280a and 280b are disposed, respectively.

The robot arms 280a and 280b are configured to be rotatable, extensible, contractible and vertically movable. The robot arms 280a and 280b can transfer wafers between the PMs 230 and the LLMs 240 while holding the wafers on forks 281a and 281b disposed at tip ends thereof, respectively. Further, the robot arms 280a and 280b can transfer consumable members such as an edge ring or the like between the PMs 230 and the storage module 270 while holding the consumable members on the forks 281a and 281b, respectively. The robot arms 280a and 280b are not limited to those shown in FIG. 2 as long as they can transfer the wafers between the PMs 230 and the LLMs 240 and transfer the consumable members between the PMs 230 and the storage module 270.

Each PM 230 has a processing chamber where a cylindrical substrate support is disposed. After the wafer is placed on the substrate support, a pressure in the PM 230 is reduced and a processing gas is introduced. Then, a radio frequency power is applied into the PM 230 to generate plasma, and plasma processing is performed on the wafer by the plasma. The VTMs 220a and 220b are partitioned from the PMs 230 by gate valves 231. Disposed on the substrate support in the PM 230 are an edge ring that surrounds the wafer to improve the uniformity of the plasma processing and a cover ring for protecting an edge of the substrate support from the plasma. Further, an upper electrode for applying a radio frequency power is disposed at an upper portion of the processing chamber facing the substrate support.

The LLMs 240 are disposed between the VTM 220a and the EFEM 250. Each of the LLMs 240 has a chamber of which inner pressure can be switched between a vacuum state and an atmospheric pressure, and a cylindrical substrate support disposed therein. In the case of loading the wafer from the EFEM 250 into the VTM 220a, the wafer is transferred from the EFEM 250 into the LLM 240 maintained at an atmospheric pressure; the pressure in the LLM 240 is decreased; and the wafer is loaded into the VTM 220a. In the case of unloading the wafer from the VTM 220a into the EFEM 250, the wafer is transferred from the VTM 220a into the LLM 240 maintained in a vacuum state; the pressure in the LLM 240 is increased to an atmospheric pressure; and the wafer W is loaded into the EFEM 250. The LLMs 240 are partitioned from the VTM 220a by gate valves 242. Further, the LLMs 240 are partitioned from the EFEM 250 by gate valves 241.

The EFEM 250 is disposed to be opposite to the VTM 220a. The EFEM 250 is a rectangular parallelepiped-shaped atmospheric transfer chamber having a fan filter unit (FFU) and maintained at an atmospheric pressure. The two LLMs 240 are connected to one long side of the EFEM 250. Five load ports (LP) 251 are connected to the other long side of the EFEM 250. A front opening unified pod (FOUP) (not shown) that is a container accommodating a plurality of wafers is placed on each LP 251. An atmospheric transfer robot (robot arm) for transferring a wafer is disposed in the EFEM 250.

The ashing module 260 is connected to the VTM 220b. The ashing module 260 has a cylindrical substrate support therein. The ashing module 260 removes a resist of the wafer placed on the substrate support. The VTM 220b is partitioned from the ashing module 260 by a gate valve 261.

The storage module 270 is connected to the VTM 220b. The storage module 270 includes a storage device for storing consumable members such as the edge ring, the cover ring, and the upper electrode. Further, the storage module 270 includes the stage (substrate support) and a rotating device for aligning the consumable members. The storage module 270 can move the consumable member from the storage device to the stage using the fork 281b of the robot arm 280b. The aligned consumable member is transferred to the PM 230 by the robot arm 280b. The VTM 220b is partitioned from the storage module 270 by a gate valve 271.

The substrate processing system 5 includes the controller 200. The controller 100 is, for example, a computer, and includes a central processing unit (CPU), a random access memory (RAM), a read only memory (ROM), an auxiliary storage device, and the like. The CPU operates based on a program stored in the ROM or the auxiliary storage device. The CPU controls operations of individual components of the substrate processing system 5.

[symbol] Method of Transferring Annular Member

[symbol]

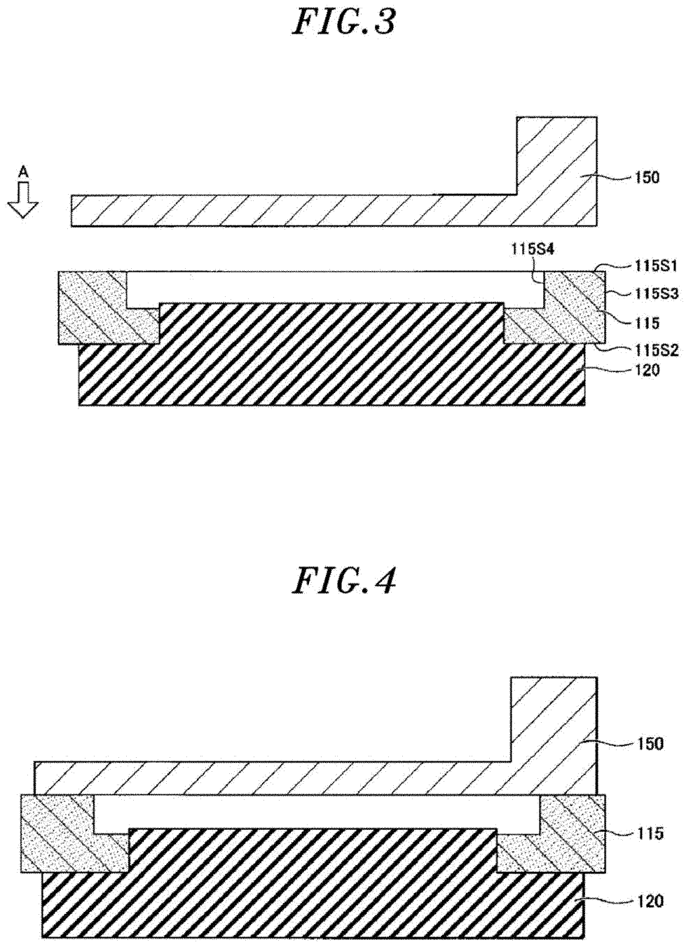

FIGS. 3 to 5 explain a method of transferring an annular member 115 of the plasma processing system 6 that is an example of the plasma processing system according to the embodiment. FIGS. 3 to 5 are cross-sectional views of a substrate support 120, the annular member 115, and a transfer arm 150. Here, one of the annular members of the ring assembly 112 is illustrated as the annular member 115. The annular member 115 is, e.g., an edge ring 112a, a cover ring 112b, or the like.

The substrate support 120 is the main body 111 of the substrate support 11 of the plasma processing system 6. As shown in FIG. 3, the transfer arm 150 is moved to be located above the substrate support 120 and the annular member 115.

The annular member 115 has a bottom surface 115S2 to be in contact with the substrate support 120, an upper surface 115S1 on the opposite side of the bottom surface 115 S2, and side surfaces 115S3 and 115S4 that connect the upper surface 115S1 and the bottom surface 115S2.

The transfer arm 150 moves in a vertical direction along an arrow A. Then, as shown in FIG. 4, the transfer arm 150 is brought into contact with the annular member 115. Specifically, the transfer arm 150 is brought into contact with the upper surface 115S1 of the annular member 115.

Next, the transfer arm 150 holds the upper surface or the side surface of the annular member 115 in an area P and moves along an arrow B. Then, the transfer arm 150 unloads the annular member 115 from the plasma processing chamber 10. In the case of loading the annular member 115, the operation of loading the annular member 115 is performed in a reverse order.

Next, a method of holding the annular member 115 using the transfer arm 150 will be described.

<Holding Using Electrostatic Force>

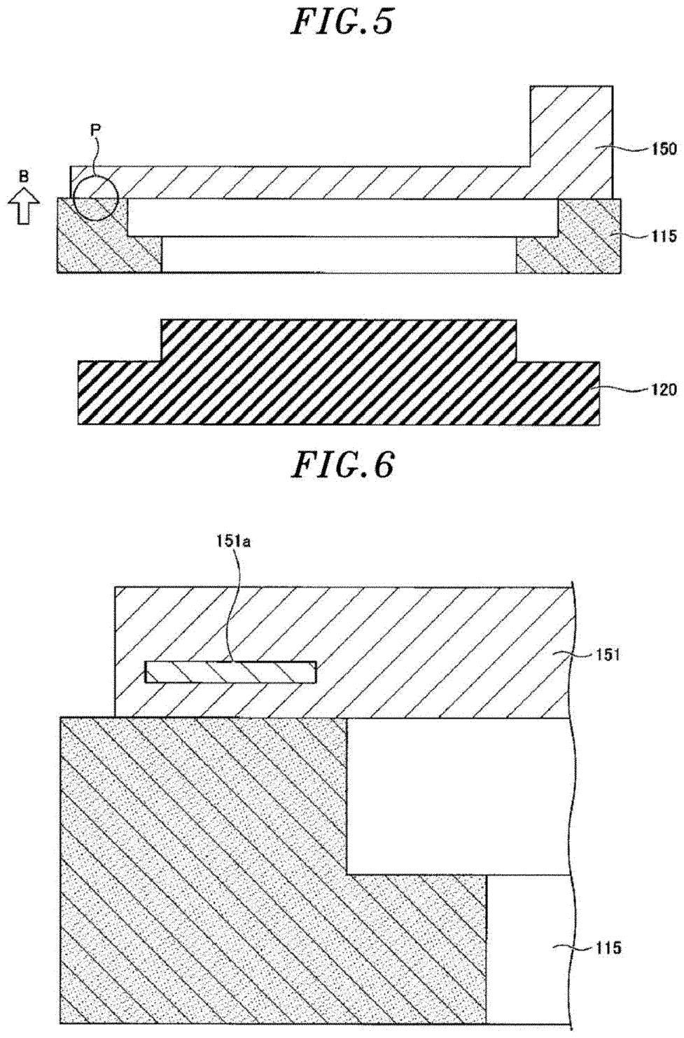

The transfer arm 151 for holding the annular member 115 using an electrostatic force will be described. FIG. 6 explains a holding method using an electrostatic force in a method of transferring the annular member 115 that is an example of an annular member in the plasma processing system according to the embodiment. In the following, an enlarged view of the area P of FIG. 5 is illustrated.

The transfer arm 151 includes an electrode 151a. A DC voltage is supplied to the electrode 151a. By supplying a DC voltage to the electrode 151a, the transfer arm 151 attracts the annular member 115 using an electrostatic force. In other words, the transfer arm 151 holds the annular member 115 using the electrostatic force generated by supplying a voltage to the electrode 151a.

<Holding Using Magnetic Force>

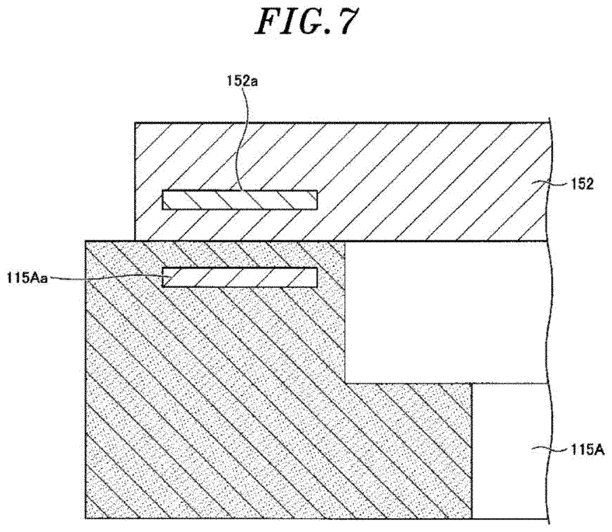

A transfer arm 152 for holding an annular member 115A using a magnetic force will be described. FIG. 7 explains a holding method using a magnetic force in a method of transferring the annular member 115A that is an example of the annular member of the plasma processing system according to the embodiment.

The transfer arm 152 includes an electromagnet 152a. Further, the annular member 115A includes a magnetic material layer 115Aa made of a magnetic material. When the electromagnet 152a operates, the magnetic material layer 115Aa of the annular member 115A is attracted to the transfer arm 152. The transfer arm 152 holds the annular member 115A using the magnetic force generated by the electromagnet 152a.

<Holding Using Adhesive Strength>

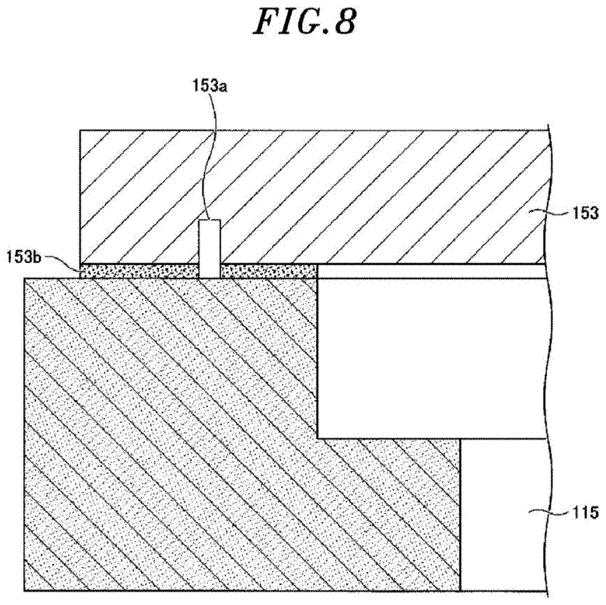

The transfer arm 153 for holding the annular member 115 using an adhesive strength will be described. FIGS. 8 and 9 explain a holding method using an adhesive strength in the method of transferring the annular member 115 that is an example of the annular member of the plasma processing system according to the embodiment.

The transfer arm 153 has an adhesive layer 153b. The transfer arm 153 further has a movable member 153a for separating the annular member 115 from the transfer arm 153.

The transfer arm 153 holds the annular member 115 due to the adhesive strength of the adhesive layer 153b. In order to separate the annular member 115, the movable member 153a protrudes toward the annular member 115. Since the movable member 153a of the transfer arm 153 protrudes, the annular member 115 adhered by the adhesive strength is separated.

<Holding Using Suction Force>

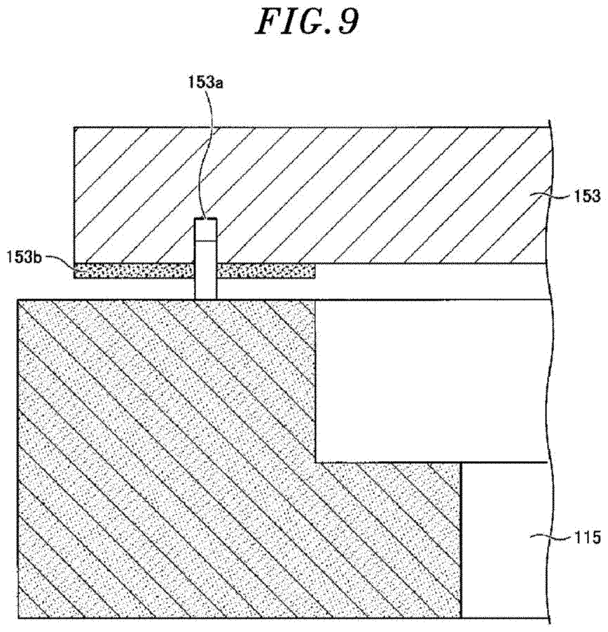

The transfer arm 154 for holding the annular member 115 using a suction force will be described. FIG. 10 explains a holding method using a suction force in a method of transferring the annular member 115 that is an example of the annular member of the plasma processing system according to the embodiment.

The transfer arm 154 has an exhaust passage 154a. The transfer arm 154 further has an elastic layer 154b. The elastic layer 154b is a member for ensuring airtightness between the transfer arm 154 and the annular member 115.

In the transfer arm 154, a gas in the plasma processing chamber 10 is discharged from the exhaust passage 154a. By discharging the gas in the plasma processing chamber 10 from the exhaust passage 154a, a negative pressure is generated between the transfer arm 154 and the annular member 115. Due to a negative pressure between the transfer arm 154 and the annular member 115, the annular member 115 is held by the transfer arm 154.

In the case of separating the annular member 115 from the transfer arm 154, a gas may be supplied from the exhaust passage 154a to separate the annular member 115.

As in the transfer arm 155 shown in FIG. 11, an elastic member 155b such as an O-ring or the like may be disposed around an outlet of the exhaust passage 155a, instead of the elastic layer 154b.

The exhaust passage 154a is an example of a suction portion.

<Holding Using Gripping Force>

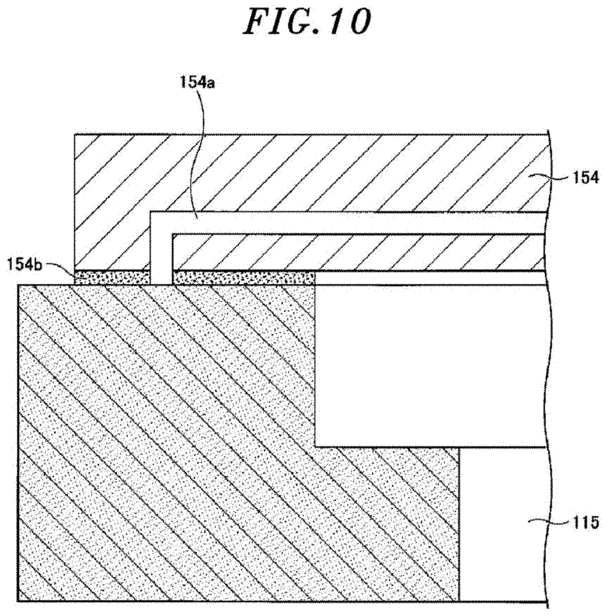

A transfer arm 156 for holding the annular member 115 using a gripping force will be described. FIG. 12 explains a holding method using a gripping force in the method of transferring the annular member 115 that is an example of the annular member of the plasma processing system according to the embodiment.

The transfer arm 156 has gripping devices 156a and 156b for gripping an outer side surface of the annular member 115.

The transfer arm 156 holds the annular member 115 by moving the portions of the gripping devices 156a and 156b that grip the annular member 115 along an arrow C.

Grooves or holes may be formed at portions of the annular member 115 that are gripped by the gripping devices 156a and 156b.

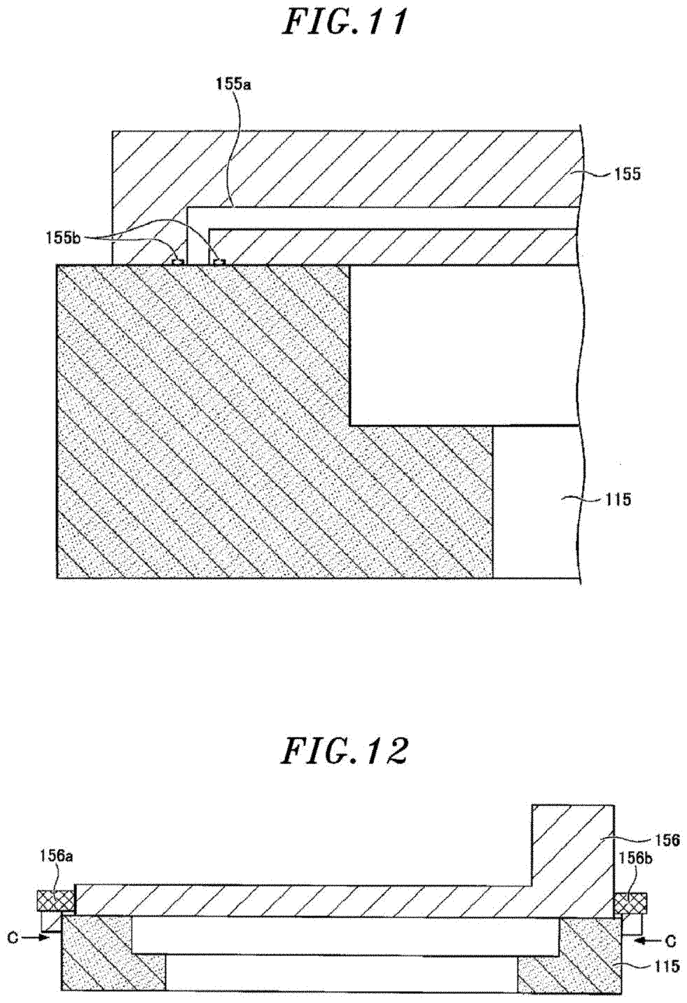

Further, as in the transfer arm 157 shown in FIG. 13, the inner side surface of the annular member 115 may be gripped by moving gripping devices 157a and 157b along an arrow D. Grooves or holes may be formed at portions of the annular member 115 that are gripped by the gripping devices 157a and 157b.

<Holding Using Intermolecular Force>

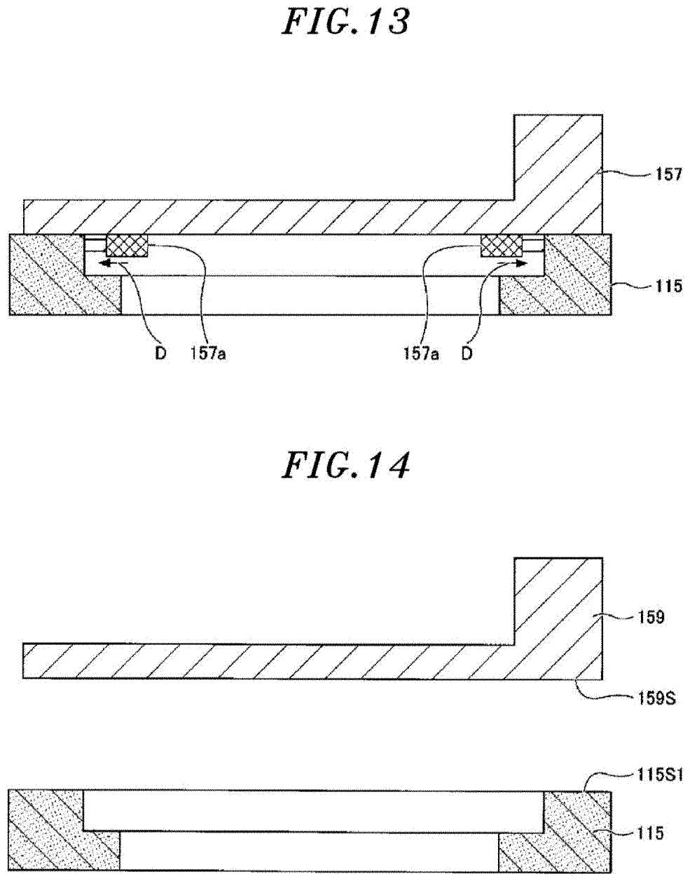

A transfer arm 159 for holding the annular member 115 using an intramolecular force will be described. FIG. 14 explains a holding method using an intramolecular force in the method of transferring the annular member 115 that is an example of the annular member of the plasma processing system according to the embodiment.

The transfer arm 159 has a mirror-finished bottom surface 159S. Further, the upper surface 115S of the annular member 115 is mirror-finished. When the bottom surface 159S of the transfer arm 159 and the upper surface 11551 of the annular member 115 are brought into contact with each other and rubbed against each other, they are in close contact with each other (ringing).

The transfer arm 159 attracts and holds the annular member 115 due to ringing, e.g., an intermolecular force. For example, in the case of loading a new annular member 115 into the plasma processing chamber 10, the upper surface 115S1 of the annular member 115 is mirror-finished. By mirror-finishing the bottom surface 159S of the transfer arm 159, the transfer arm 159 can hold the annular member 115. After the annular member 115 is used, the surface of the annular member 115 becomes rough. Therefore, the used annular member 115 can be unloaded by the transfer arm 153 for holding the annular member 115 using an adhesive strength.

The mirror-finished bottom surface 159S of the transfer arm 159 is an example of an attracting portion.

<Holding of the Wafer W and the Annular Member 115 by the Transfer Arm>

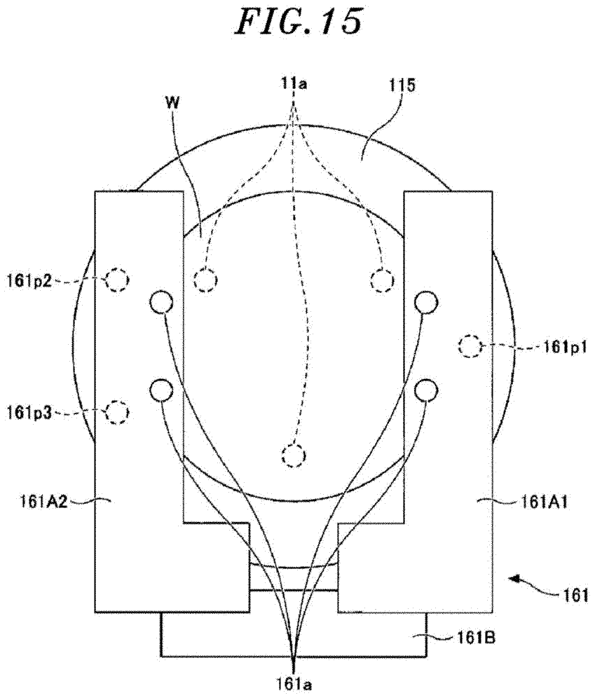

FIG. 15 explains a transfer arm 161 that is an example of the transfer arm of the plasma processing system according to the embodiment. The transfer arm 161 can transfer the substrate W and the annular member 115.

The transfer arm 161 has arms 161A1 and 161A2, and a slide mechanism 161B capable of changing a distance between the arm 1611A and the arm 161A2. The transfer arm 161 further has a plurality of wafer placing members 161a for placing the wafer W on the upper surfaces of the arm 161A1 and 161A2.

In the case of transferring the wafer W, the transfer arm 161 is moved to a position below the wafer W. Then, the transfer arm 161 lifts the wafer W from the position therebelow. The wafer placing members 161a prevent direct contact between the wafer W and the upper surface of the transfer arm 161. The wafer placing members 161a are flexible members. The transfer arm 161 of FIG. 15 has four wafer placing members 161a. The number of wafer placing members is not limited to four, and at least three or more wafer placing members may be provided.

In the case of transferring the annular member 115, the transfer arm 161 is moved to a position above the annular member 115. Then, the transfer arm 161 holds the annular member 115 using annular member holders 161p1, 161p2, and 161p3 disposed below the transfer arm 161. Then, the transfer arm 161 transfers the annular member 115. The number of the annular member holders is not limited to three, and at least three or more annular member holders may be provided. In other words, the transfer arm 161 holds the annular member 115 at three or more locations.

For example, when the transfer arm 161 holds the annular member 115 using an electrostatic force, the annular member 115 may be held by an electrode disposed at two locations of each of the arms 161A1 and 161A2, for example, by lengthening the shape of the electrode.

Since the transfer arm 161 has the slide mechanism 161B capable of changing the distance between the arm 161A1 and the arm 161A2, the transfer arm 161 can transfer the wafer W and the annular member 115 of various dimensions.

When the dimensions of the wafer W and the annular member 115 are fixed, the arm 161A1 and the arm 161A2 may be integrated without using the slide mechanism 161B of the transfer arm 161.

Further, the transfer arm 161 may transfer only the annular member 115, and the substrate W may be transferred by another transfer arm. When the substrate W is transferred by a transfer arm different from the transfer arm 161, a robot arm including the transfer arm 161 and a robot arm including the transfer arm for transferring the substrate W may be provided. Further, both the transfer arm for transferring the substrate W and the transfer arm 161 may be disposed at the tip end of the robot arm. For example, in the case of providing the transfer arm for transferring the substrate W on the upper side of the tip end of the robot arm and the transfer arm 161 on the lower side of the tip end of the robot arm, the transfer arm for transferring the substrate W may be used to transfer the substrate W and the transfer arm 161 may be used to transfer the annular member 115.

The arm 161A1 and the arm 161A2 are examples of a first arm and a second arm, respectively.

The transfer arm according to the embodiment load/unloads the annular member into/from the processing chamber while holding the upper surface or the side surface of the annular member. Therefore, the annular member can be transferred without providing a mechanism for raising and lowering the annular member at the substrate support, for example. When the substrate support is provided with the mechanism for raising and lowering the annular member, a singular point of temperature or abnormal discharge occurs. Further, if the substrate support is provided with the mechanism for raising and lowering the annular member, a mechanism for separating atmosphere and vacuum is required.

The transfer arm according to the embodiment can prevent occurrence of a singular point of temperature or abnormal discharge. Further, the transfer arm according to the embodiment does not requires the mechanism for separating atmosphere and vacuum, which makes it possible to simplify the structure of the substrate support.

The plasma processing system, the transfer arm, and the method of transferring an annular member according to the embodiments of the present disclosure are considered to be illustrative in all respects and not restrictive. The above-described embodiments can be changed and modified in various forms without departing from the scope of the appended claims and the gist thereof. The above-described embodiments may include other configurations without contradicting each other and may be combined without contradicting each other.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A plasma processing system comprising:
a processing chamber;
a substrate support disposed in the processing chamber;
an annular member disposed at an outer edge of the substrate support and having a bottom surface in contact with the substrate support, an upper surface on the opposite side of the bottom surface, and a side surface that connects the upper surface and the bottom surface; and
a transfer arm configured to load/unload the annular member into/from the processing chamber while holding the upper surface or the side surface.

2. The plasma processing system of claim 1, wherein the annular member has a magnetic material layer,
the transfer arm has an electromagnet configured to attract the magnetic material layer, and
the transfer arm holds the annular member due to attraction of the magnetic material, layer by the electromagnet.

3. The plasma processing system of claim 1, wherein the transfer arm has an electrostatic chuck, and
the transfer arm holds the annular member due to attraction of the annular member by the electrostatic chuck.

4. The plasma processing system of claim 1, wherein the transfer arm has an adhesive layer, and
the transfer arm holds the annular member due to adhesion of the adhesive layer to the annular member.

5. The plasma processing system of claim 1, wherein the transfer arm has a suction portion configured to suck a gas in the processing chamber, and
the transfer arm holds the annular member due to suction of the annular member by the suction portion.

6. The plasma processing system of claim 1, wherein the transfer arm includes a mirror-finished attracting portion, and
the transfer arm holds the annular member due to attraction of the suction portion and the annular member by an intermolecular force.

7. The plasma processing system of claim 1, wherein the transfer arm holds the annular member at three or more locations.

8. The plasma processing system of claim 1, wherein the transfer arm has:
a first arm;
a second arm; and
a slide mechanism configured to change a distance between the first arm and the second arm.

9. A transfer arm configured to load/unload an annular member into/from a processing chamber in a plasma processing apparatus including the processing chamber, a substrate support disposed in the processing chamber, and the annular member, the annular member being disposed at an outer edge of the substrate support and having a bottom surface in contact with the substrate support, an upper surface on the opposite side of the bottom surface, and a side surface that connects the upper surface and the bottom surface,
wherein the transfer arm loads/unloads the annular member into/from the processing chamber while holding the upper surface or the side surface.

10. A method of transferring an annular member loaded into or unloaded from a processing chamber in a plasma processing apparatus including the processing chamber, a substrate support disposed in the processing chamber, and the annular member, the annular member being disposed at an outer edge of the substrate support and having a bottom surface in contact with the substrate support, an upper surface on the opposite side of the bottom surface, and a side surface that connects the upper surface and the bottom surface,
wherein the method comprising:
loading/unloading the annular member into/from the processing chamber while holding the upper surface of the side surface.
